(19) United States
(12) Patent Application Publication
(10) Pub. No.: US 2026/0164736 A1
(43) Pub. Date: Jun. 11, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Younjin JANG, Suwon-si (KR); Jeeeun YANG, Suwon-si (KR); Sangwook KIM, Suwon-si (KR)

(73) Assignee: Samsung Electronics Co., Ltd., Suwon-si (KR)

(21) Appl. No.: 19/210,487

(22) Filed: May 16, 2025

(30) Foreign Application Priority Data
Dec. 11, 2024 (KR) 10-2024-0184167

(51) Int. Cl. H10D 62/60; H10B 12/00; H10D 30/01; H10D 30/63; H10D 62/00; H10D 62/10; H10D 62/80

(52) U.S. Cl. CPC H10D 62/60; H10D 30/025; H10D 30/63; H10D 62/01; H10D 62/117; H10D 62/875; H10B 12/30

(57) ABSTRACT

Provided are a semiconductor device and a method of manufacturing the same. The semiconductor device may include a first electrode, a second electrode spaced apart from the first electrode, an oxide semiconductor layer between the first electrode and the second electrode, a metal oxide layer between the oxide semiconductor layer and the first electrode, a gate insulating layer, and a gate electrode. The metal oxide layer may include indium and at least one metal among tungsten (W) and ruthenium (Ru). The gate insulating layer may be between the gate electrode and the oxide semiconductor layer.

### CROSS-REFERENCE TO RELATED APPLICATION

This application is based on and claims priority under 35 U.S.C. § 119 to Korean Patent Application No. 10-2024-0184167, filed on Dec. 11, 2024, in the Korean Intellectual Property Office, the disclosure of which is incorporated by reference herein in its entirety.

### BACKGROUND

### 1. Field

The disclosure relates to a semiconductor device having reduced contact resistance and/or a method of manufacturing the same.

### 2. Description of the Related Art

A transistor is a semiconductor device that serves as an electrical switching device and may be used in various integrated circuit devices including memory, a driving integrated circuit (IC), a logic device, and the like. In order to increase the integration of integrated circuit devices, a space occupied by transistors arranged thereon is rapidly shrinking, and research is being conducted to reduce the size of transistors while maintaining their performance.

An oxide semiconductor transistor uses an oxide semiconductor material as a channel layer. The channel layer may have higher mobility even in an amorphous state compared to when silicon is used as the channel layer and may be uniformly formed in a large area. In addition, oxide semiconductor transistors may have a low leakage current based on the characteristics of a wide bandgap of 3.0 eV or more and a small hole carrier concentration.

However, when oxide semiconductor transistors are applied as semiconductor oriented devices, contact resistance may have a significant impact on the operating performance of the transistor as the size of the transistor decreases. For example, the total resistance of the transistor may be determined by the sum of the resistance of the channel layer and the contact resistance between an electrode (e.g., source or drain electrode) and the channel layer. The total resistance of the transistor may be more affected by the size of the contact resistance as the length of the channel layer decreases. Contact resistance may increase due to a metal reacting with a strong oxidizing agent such as ozone during the manufacturing process and may increase further due to subsequent high-temperature processes.

### SUMMARY

Provided is a semiconductor device having reduced contact resistance.

Provided is a method of manufacturing a semiconductor device having reduced contact resistance.

Additional aspects will be set forth in part in the description which follows and, in part, will be apparent from the description, or may be learned by practice of the presented embodiments of the disclosure.

According to an example embodiment of the disclosure, a semiconductor device may include a first electrode; a second electrode spaced apart from the first electrode; an oxide semiconductor layer between the first electrode and the second electrode; a metal oxide layer between the oxide semiconductor layer and the first electrode, the metal oxide layer including indium (In) and a metal, and the metal including at least one of tungsten (W) and ruthenium (Ru); a gate insulating layer provided on the oxide semiconductor layer; and a gate electrode on the gate insulating layer. The gate insulating layer may be between the oxide semiconductor layer and the gate electrode. The metal oxide layer may include a local region in which a content of the metal may be greater than 0 at % and less than or equal to 20 at %, and a sum of a content of the indium and the content of the metal may be more than or equal to 60 at %.

In some embodiments, the local region may be located in a region of 20% to 80% of a thickness of the metal oxide layer from a boundary between the first electrode and the metal oxide layer.

In some embodiments, a region in which the content of the indium in the metal oxide layer is higher than the content of the metal may be located in a region of 20% or more of a thickness of the metal oxide layer from a boundary between the first electrode and the metal oxide layer.

In some embodiments, a buffer layer including at least one of InO and ITO may be further provided between the metal oxide layer and the oxide semiconductor layer.

In some embodiments, the first electrode further comprises Zn, and a content of Zn in the first electrode may be greater than 0 at % and less than or equal to 10 at %.

In some embodiments, a second metal oxide layer may be between the oxide semiconductor layer and the second electrode. The metal oxide layer between the oxide semiconductor layer and the first electrode may be a first metal oxide layer, and the second metal oxide layer may include the local region.

In some embodiments, the oxide semiconductor layer may include at least one of In, Zn, Sn, Ga, and Hf.

In some embodiments, the content of the metal in the metal oxide layer may be greater in a region relatively closer to the first electrode than in a region relatively far from the first electrode.

In some embodiments, the gate electrode may be provided to surround a periphery of the oxide semiconductor layer.

In some embodiments, the semiconductor device may further include a substrate. The oxide semiconductor layer, the gate insulating layer, and the gate electrode may be disposed in a horizontal direction on a surface of the substrate. The oxide semiconductor layer, the gate insulating layer, and the gate electrode may extend lengthwise in a direction that may be perpendicular to the surface of the substrate.

In some embodiments, a bottom portion of the oxide semiconductor layer may contact the first electrode. A first vertical extension portion of the oxide semiconductor layer may extend perpendicular to the first electrode from a first end of the bottom portion, and a second vertical extension portion of the oxide semiconductor layer may extend perpendicular to the first electrode from a second end of the bottom portion.

In some embodiments, a capacitor may be electrically connected to the first electrode or the second electrode.

According to an example embodiment of the disclosure, a method of manufacturing a semiconductor device may include forming a first electrode including at least one of tungsten (W) and ruthenium (Ru); forming a buffer layer including indium (In) on the first electrode; forming an oxide semiconductor layer on the buffer layer; and forming a metal oxide layer between the first electrode and the oxide semiconductor layer by performing a heat treatment on a structure including the first electrode, the buffer layer, and the oxide semiconductor layer. The metal oxide layer may include a metal and the metal may include at least one of indium, tungsten (W), and ruthenium (Ru). The metal oxide layer may include a local region in which a content of the metal may be greater than 0 at % and less than or equal to 20 at %, and a sum of a content of the indium and the content of the metal is more than or equal to 60 at %.

In some embodiments, the buffer layer may have a thickness greater than 3 nm and less than or equal to 7 nm.

In some embodiments, the heat treatment may be performed at a temperature of 400° C. to 600° C.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a semiconductor device according to an embodiment;

FIG. 2 illustrates an example in which a buffer layer is further provided in the semiconductor device illustrated in FIG. 1;

FIG. 3 illustrates a semiconductor device according to another embodiment;

FIG. 4 illustrates a semiconductor device according to another embodiment;

FIG. 5 illustrates a modified example of an oxide semiconductor layer in the semiconductor device of FIG. 4;

FIG. 6 illustrates a modified example of a metal oxide layer in the semiconductor device of FIG. 4;

FIG. 7 illustrates a semiconductor device according to another embodiment;

FIG. 8 illustrates a flowchart of a method of manufacturing a semiconductor device according to an embodiment;

FIG. 9A is a graph illustrating a composition analysis result according to a position of a semiconductor device in a thickness direction according to an embodiment;

FIG. 9B illustrates, as a table, energy dispersive X-ray spectroscopy (EDS) analysis results for a metal oxide layer of a semiconductor device according to an embodiment;

FIG. 10A is a graph illustrating a composition analysis result according to a position of a semiconductor device in a thickness direction according to a comparative example;

FIG. 10B illustrates, as a table, EDS analysis results for a metal oxide layer of a semiconductor device according to a comparative example;

FIG. 11 illustrates V-I graphs of a semiconductor device according to comparative examples and a semiconductor device according to embodiments;

FIGS. 12 to 21 are diagrams for describing a method of manufacturing a semiconductor device according to an embodiment;

FIG. 22 illustrates an example in which a semiconductor device according to an embodiment is applied to a dynamic random access memory (DRAM);

FIG. 23 illustrates an example in which a semiconductor device according to an embodiment is applied to a vertically stacked memory device;

FIG. 24 illustrates an example in which a semiconductor device according to an embodiment is applied to another vertically stacked memory device;

FIG. 25 is a schematic block diagram of a display driver integrated circuit (IC) (DDI) including a semiconductor device according to an embodiment and a display device including the DDI;

FIG. 26 is a circuit diagram of a complementary metal oxide semiconductor (CMOS) inverter including a semiconductor device according to an embodiment;

FIG. 27 is a circuit diagram of a CMOS static RAM (SRAM) device including a semiconductor device according to an embodiment;

FIG. 28 is a circuit diagram of a CMOS NAND circuit including a semiconductor device according to an embodiment;

FIG. 29 is a block diagram of an electronic system including a semiconductor device according to an embodiment; and

FIG. 30 is a block diagram of an electronic system including a semiconductor device according to an embodiment.

### DETAILED DESCRIPTION

Reference will now be made in detail to embodiments, Examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, a semiconductor device and a method of manufacturing the same according to various embodiments will be described in detail with reference to the accompanying drawings. In the following drawings, the same reference numerals refer to the same components, and the size of each component in the drawings may be exaggerated for clarity and convenience of description. The terms first, second, etc. may be used to describe various components, but the components should not be limited by the terms. The terms are used only for the purpose of distinguishing one component from other components.

The singular expression includes plural expressions unless the context clearly implies otherwise. In addition, when a part “includes” a component, this means that it may further include other components, not excluding other components unless otherwise stated. In addition, the size or thickness of each component in the drawing may be exaggerated for clarity of explanation. Additionally, when a desired and/or alternatively predetermined material layer is described as being on a substrate or another layer, the material layer may exist in direct contact with the substrate or the other layer, or another third layer may exist in between. In addition, since the materials constituting each layer in the embodiments below are only examples, other materials may be used.

Further, the terms “unit”, “module” or the like mean a unit that processes at least one function or operation, which may be implemented in hardware or software or implemented in a combination of hardware and software.

The specific implementations described in the present embodiment are examples and do not limit the technical scope in any way. For simplicity of the specification, descriptions of conventional electronic configurations, control systems, software, and other functional aspects of the systems may be omitted. In addition, the connection or connection members of lines between the components shown in the drawings exemplarily may be used as an example to represent functional connection and/or physical or circuit connections, and may be replaceable or represented as various additional functional connections, physical connections, or circuit connections in an actual device.

The use of the term “the” and similar indicative terms may correspond to both singular and plural.

Operations constituting the method may be performed in an appropriate order unless there is a clear statement that the operations should be performed in the order described. In addition, the use of all illustrative terms (e.g., etc.) is simply intended to detail technical ideas and, unless limited by the claims, the scope of rights is not limited due to the terms.

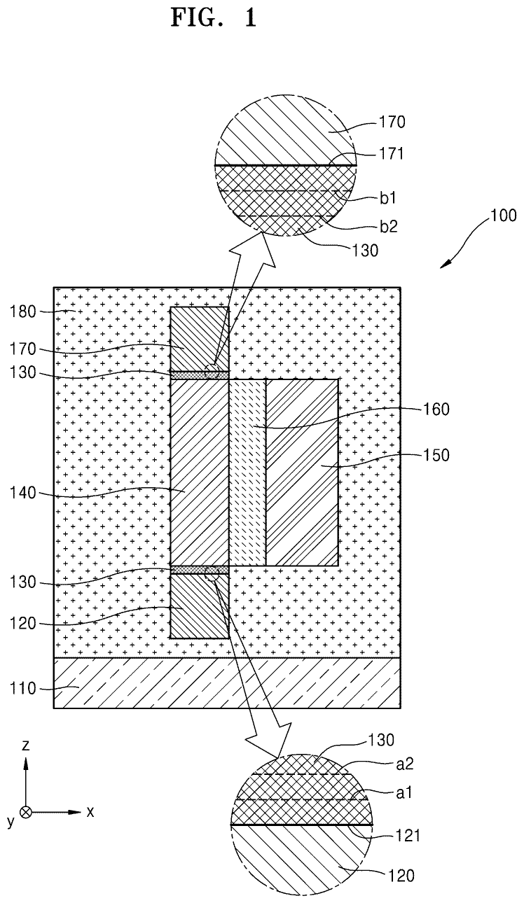

FIG. 1 illustrates a semiconductor device according to an embodiment.

Referring to FIG. 1, a semiconductor device 100 includes a substrate 110, an oxide semiconductor layer 140 on the substrate 110, a first electrode 120 on the oxide semiconductor layer 140, and a second electrode 170 on the oxide semiconductor layer 140 to be spaced apart from the first electrode 120. A metal oxide layer 130 including indium may be provided at least one of on between the oxide semiconductor layer 140 and the first electrode 120 and between the oxide semiconductor layer 140 and the second electrode 170. In FIG. 1, an example in which the metal oxide layers 130 are respectively provided between the oxide semiconductor layer 140 and the first electrode 120 and between the oxide semiconductor layer 140 and the second electrode 170 is illustrated. The first electrode 120 may be a source electrode, and the second electrode 170 may be a drain electrode.

The substrate 110 may be an insulating substrate or may be a semiconductor substrate having an insulating layer formed on the surface thereof. Alternatively, the substrate 110 may be a semiconductor substrate. The semiconductor substrate may include, for example, Si, Ge, SiGe, or a group III-V semiconductor material. The substrate 110 may be, for example, a silicon substrate having a silicon oxide formed on a surface thereof but is not limited thereto.

The first electrode 120 may include a metal material. The first electrode 120 may include at least one of tungsten (W) and ruthenium (Ru). The first electrode 120 may be spaced apart from the substrate 110. In addition, the first electrode 120 may further include Zn having a content of 10 at % or less. Zn may have a content of 10 at % or less with respect to all metal elements in the first electrode 120. Here, the content of Zn may represent the content of Zn with respect to all metal elements included in the first electrode 120 except for oxygen. Alternatively, the first electrode 120 may include Zn having a content of 5 at % or less.

The metal oxide layer 130 may include a metal including at least one of metals included in the first electrode 120 or the second electrode 170. In other words, the metal oxide layer 130 may include indium (In), metal (M), and oxygen (O). The metal M may include at least one of W and Ru. For example, the metal oxide layer 130 may include InWO and/or InRuO. The metal oxide layer 130 may be arranged to be in direct contact with the first electrode 120 and the oxide semiconductor layer 140 or may be arranged to be in direct contact with the second electrode 170 and the oxide semiconductor layer 140. Alternatively, the metal oxide layer 130 may be arranged to be in direct contact with only one of the first electrode 120 and the oxide semiconductor layer 140. Alternatively, the metal oxide layer 130 may be arranged to be in direct contact with only one of the second electrode 170 and the oxide semiconductor layer 140. However, the metal oxide layer 130 is not limited thereto.

The content of the metal M of the metal oxide layer 130 may be greater in a region relatively close to the first electrode 120 than in a region relatively far from the first electrode 120. Referring to FIG. 1, the content of the metal M at a position a1 of the metal oxide layer 130 is greater than the content of the metal M at a position a2, and the positions a1 and a2 are respectively located at distances a1 and a2 from a boundary surface 121 between the first electrode 120 and the metal oxide layer 130, and a1<a2. Alternatively, the content of the metal M of the metal oxide layer 130 may have a gradation content distribution that gradually decreases as it approaches the oxide semiconductor layer 140.

The content of the metal M of the metal oxide layer 130 may be greater in a region relatively close to the second electrode 170 than in a region relatively far from the second electrode 170. The content of the metal M at a position b1 of the metal oxide layer 130 is greater than the content of the metal M at a position b2, and the positions b1 and b2 are respectively located at distances b1 and b2 from a boundary surface 171 between the second electrode 170 and the metal oxide layer 130, and b1<b2. Alternatively, the content of the metal M of the metal oxide layer 130 may have a gradation content distribution that gradually decreases as it approaches the oxide semiconductor layer 140.

The metal oxide layer 130 may include a local region where the content of the metal M is greater than 0 and less than or equal to 20 at %, and the sum of the content of the metal M and the content of indium is 60 at % or more. Here, the content may represent a ratio of the content of the corresponding element to other elements except oxygen in the metal oxide layer 130. In the metal oxide layer 130, the local region may be provided in a region of 20% to 80% of the thickness of the metal oxide layer 130 from the boundary surface 121 between the first electrode 120 and the metal oxide layer 130. In the metal oxide layer 130, the local region may be provided in a region of 20% to 80% of the thickness of the metal oxide layer 130 from the boundary surface 171 between the second electrode 170 and the metal oxide layer 130.

A region in which the content of indium in the metal oxide layer 130 is greater than the content of metal M may be provided in a region of 20% or more of the thickness of the metal oxide layer 130 from the boundary surface 121 between the first electrode 120 and the metal oxide layer 130. A region in which the content of indium in the metal oxide layer 130 is greater than the content of metal M may be provided in a region of 20% or more of the thickness of the metal oxide layer 130 from the boundary surface 171 between the second electrode 170 and the metal oxide layer 130.

The oxide semiconductor layer 140 may be an oxide including at least one of indium (In), gallium (Ga), zinc (Zn), tungsten (W), tin (Sn), and hafnium (Hf). The oxide semiconductor layer 140 may include, for example, zinc indium oxide (ZIO), indium gallium oxide (IGO), or indium gallium zinc oxide (IGZO). The oxide semiconductor layer 140 may include a material selected from InGaZnO, ZrInZnO, InGaZnO, ZnInO, InO, HfInZnO, and combinations thereof.

The oxide semiconductor layer 140 includes, for example, In and Zn, and the content of In in the oxide semiconductor layer 140 may be greater than or equal to the content of Zn of the oxide semiconductor layer 140. The thickness of the oxide semiconductor layer 140 may be 1 nm or more, or 3 nm or more. The thickness of the oxide semiconductor layer 140 may be 20 nm or less, 15 nm or less, or 10 nm or less.

The first electrode 120 and the second electrode 170 may be spaced apart from the substrate 110 in a direction (z direction) perpendicular to the substrate 110, and the oxide semiconductor layer 140 may be arranged between the first electrode 120 and the second electrode 170 in a length direction. In this way, the first electrode 120, the metal oxide layer 130, the oxide semiconductor layer 140, and the second electrode 170 may be arranged in a line in a direction (z direction) perpendicular to the substrate 110. The first electrode 120, the metal oxide layer 130, the oxide semiconductor layer 140, and the second electrode 170 may have a same width.

The length direction of the oxide semiconductor layer 140 may be a direction (z direction) perpendicular to the substrate 110. The oxide semiconductor layer 140 may be used as a channel layer. The semiconductor device 100 may have a vertical channel transistor (VCT) structure including a vertical channel region where the oxide semiconductor layer 140 extends on the first electrode 120 in the vertical direction z.

In the present specification, the length direction refers to a direction in which the length of the corresponding component is long when viewed in the drawing.

A gate electrode 150 may be provided on one side of the oxide semiconductor layer 140. A gate insulating layer 160 may be provided between the oxide semiconductor layer 140 and the gate electrode 150. The gate electrode 150 may be arranged such that the length direction (z direction) thereof is the direction perpendicular to the substrate 110. The oxide semiconductor layer 140, the gate insulating layer 160, and the gate electrode 150 may be arranged in a line in a horizontal direction (x direction) with respect to the surface of the substrate 110. The gate insulating layer 160 may include an oxide including at least one of hafnium (Hf), zirconium (Zr), aluminum (Al), and silicon (Si).

A mold insulating material 180 may be provided on the substrate 110 to fill an empty space. The first electrode 120 may be spaced apart from the substrate 110 by the mold insulating material 180.

As described above, the semiconductor device 100 according to an embodiment may include the metal oxide layer 130 including indium to reduce contact resistance between the first electrode 120 and the second electrode 170 and increase on-current. An increase in contact resistance due to the metal oxide layer 130 may be suppressed by adjusting the indium content of the metal oxide layer 130.

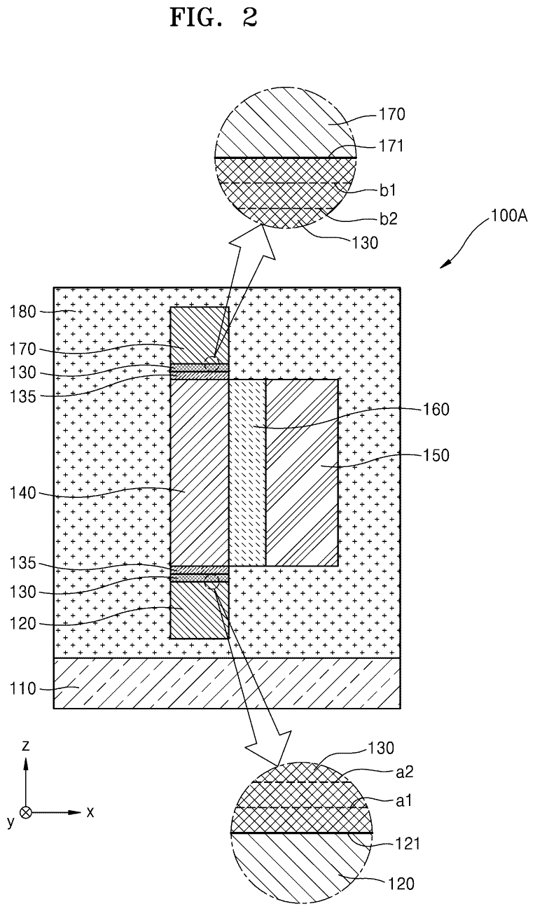

FIG. 2 illustrates an example in which a buffer layer 135 is further provided in the semiconductor device illustrated in FIG. 1. In FIG. 2, components using the similar reference numbers as in FIG. 1 have substantially the same configurations and functional effects as those described in FIG. 1, and thus the detailed description thereof will be omitted. The semiconductor device 100A may include a buffer layer 135 between the metal oxide layer 130 and the oxide semiconductor layer 140. The buffer layer 135 may not include the metal M of the metal oxide layer 130. The buffer layer 135 may include InO or ITO. The buffer layer 135 may be a layer for supplying indium to the metal oxide layer 130. The buffer layer 135 may not remain after the reaction with the metal oxide layer 130 in the manufacturing process or may partially remain. Even in the semiconductor device according to an embodiment to be described later, a buffer layer may be further provided between the metal oxide layer and the oxide semiconductor layer, although not shown in the drawings.

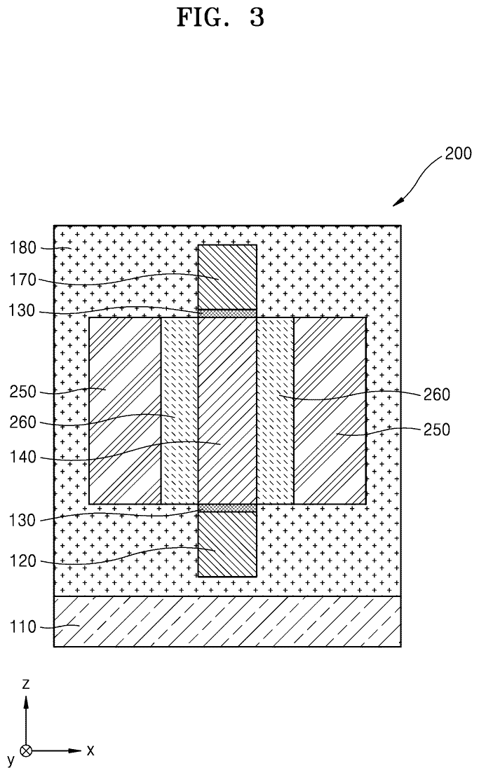

FIG. 3 illustrates a semiconductor device according to another embodiment. In FIG. 3, components using the same reference numerals as those of FIG. 1 have substantially the same configuration and effect as those described with reference to FIG. 1, and thus a detailed description thereof is omitted.

A semiconductor device 200 includes a first electrode 120, a metal oxide layer 130, an oxide semiconductor layer 140, a metal oxide layer 130, and a second electrode 170 arranged in a direction (z direction) perpendicular to a substrate 110. A gate insulating layer 260 may be provided around the oxide semiconductor layer 140, and a gate electrode 250 may be provided around the gate insulating layer 260. The gate electrode 250 may be provided around the oxide semiconductor layer 140 to increase an area in which the gate electrode 250 and the oxide semiconductor layer 140 face each other, and to improve a short channel effect. The gate insulating layer 260 may include an oxide including at least one of hafnium (Hf), zirconium (Zr), aluminum (Al), and silicon (Si).

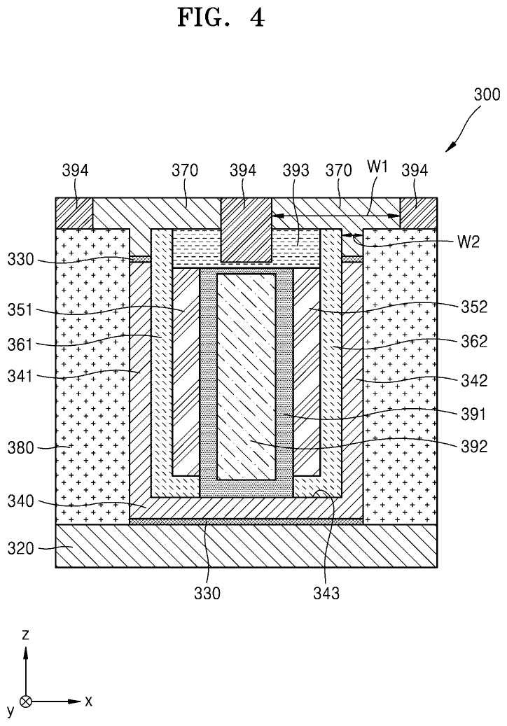

FIG. 4 illustrates a semiconductor device according to another embodiment.

A semiconductor device 300 may include a first electrode 320, a metal oxide layer 330 provided on the first electrode 320, and an oxide semiconductor layer 340 provided on the metal oxide layer 330. Since the metal oxide layer 330 has substantially the same configuration and operation effect as the metal oxide layer 130 described with reference to FIG. 1, a detailed description thereof is omitted.

The oxide semiconductor layer 340 may have a U-shaped cross-sectional shape. The oxide semiconductor layer 340 may include a bottom portion 343 in contact with the metal oxide layer 330, a first vertical extension portion 341 extending in a direction (z direction) perpendicular to the first electrode 320 from one end of the bottom portion 343, and a second vertical extension portion 342 extending in a direction (z direction) perpendicular to the first electrode 320 from the other end of the bottom portion 343.

A first gate electrode 351 may be spaced apart from the first vertical extension portion 341, and a second gate electrode 352 may be spaced apart from the second vertical extension portion 342. A first gate insulating layer 361 may be provided between the first vertical extension portion 341 and the first gate electrode 351, and a second gate insulating layer 362 may be provided between the second vertical extension portion 342 and the second gate electrode 352.

At least one of the first gate electrode 351 and the second gate electrode 352 may extend in the second horizontal direction y. The first gate electrode 351 and the second gate electrode 352 may be spaced apart from each other. At least one of the first gate electrode 351 and the second gate electrode 352 may constitute a word line WL. The electrical signal input to the first gate electrode 351 may not match the electrical signal input to the second gate electrode 352. The first gate electrode 351 may control the channel of the first vertical extension portion 341, and the second gate electrode 352 may control the channel of the second vertical extension portion 342.

An insulating liner 391 may be arranged between the first gate electrode 351 and the second gate electrode 352 spaced apart from each other. The insulating liner 391 may be conformally arranged on the side walls in which the first gate electrode 351 faces the second gate electrode 352, and/or the upper surface of the oxide semiconductor layer 340. The insulating liner 391 may have a top surface arranged on the same upper plane as the upper surfaces of the first gate electrode 351 and the second gate electrode 352. The insulating liner 391 may include, for example, silicon nitride. A buried insulating layer 392 may fill a space between the first gate electrode 351 and the second gate electrode 352 spaced apart from each other on the insulating liner 391. The buried insulating layer 392 may include, for example, silicon oxide. An upper insulating layer 393 may be arranged on the upper surfaces of the first gate electrode 351, the second gate electrode 352, and/or the buried insulating layer 392. The top surface of the upper insulating layer 393 may be arranged at the same level as the top surface of a mold insulating layer 380.

The second electrode 370 may be arranged above the oxide semiconductor layer 340. The metal oxide layer 330 may be provided between the oxide semiconductor layer 340 and the second electrode 370. The second electrode 370 may serve as a landing pad. The second electrode 370 may include a left second electrode and a right second electrode. The metal oxide layers 330 may be provided between the left second electrode and the oxide semiconductor layer 340, and between the right second electrode and the oxide semiconductor layer 340, respectively. The left second electrode may be electrically connected to the first vertical extension portion 341. The right second electrode may be electrically connected to the second vertical extension portion 342. The left second electrode and the right second electrode may not be electrically connected with each other. The second electrode 370 may include an upper portion and a lower portion. The upper portion of the second electrode 370 may be a portion of the second electrode 370 arranged at a higher level than the top surface of the mold insulating layer 380. The lower part of the second electrode 370 may be a portion of the second electrode 370 arranged inside a second electrode recess defined between the mold insulating layer 380 and the upper insulating layer 393. In an embodiment, the upper part of the second electrode 370 may have a first width W1 in the first horizontal direction x, and the lower part of the second electrode 370 may have a second width W2 smaller than the first width W1 in the first horizontal direction x. The lower part of the second electrode 370 may be arranged inside the second electrode recess, and the upper part of the second electrode 370 may have a bottom surface arranged on the top surface of the mold insulating layer 380 and the top surface of the upper insulating layer 393. Accordingly, the upper electrode 570 may have a T-shaped vertical cross-section. A bottom surface of the lower part of the second electrode 370 may contact the upper portions of the surfaces of the first vertical extension portion 341 and/or the second vertical extension portion 342. Both sidewalls of the lower portion of the second electrode 370 may be aligned with both sidewalls of the first vertical extension portion 341 and the second vertical extension portion 342. The bottom surface of the lower part of the second electrode 370 may be arranged at a higher level than the top surface of the first gate electrode 351 and/or the upper surface of the second gate electrode 352, and a portion of the sidewall of the lower part of the second electrode 370 may be covered by the first gate insulating layer 361 and/or the second gate insulating layer 362. An upper electrode insulating layer 394, which surrounds the second electrode 370, may be arranged on the upper surfaces of the mold insulating layer 380 and the upper insulating layer 393. The semiconductor device 300 may have a vertical channel transistor (VCT) structure including a vertical channel region where the oxide semiconductor layer 340 extends on the first electrode 320 in the vertical direction z. The first gate insulating layer 361 and second gate insulating layer 362 may include an oxide including at least one of hafnium (Hf), zirconium (Zr), aluminum (Al), and silicon (Si).

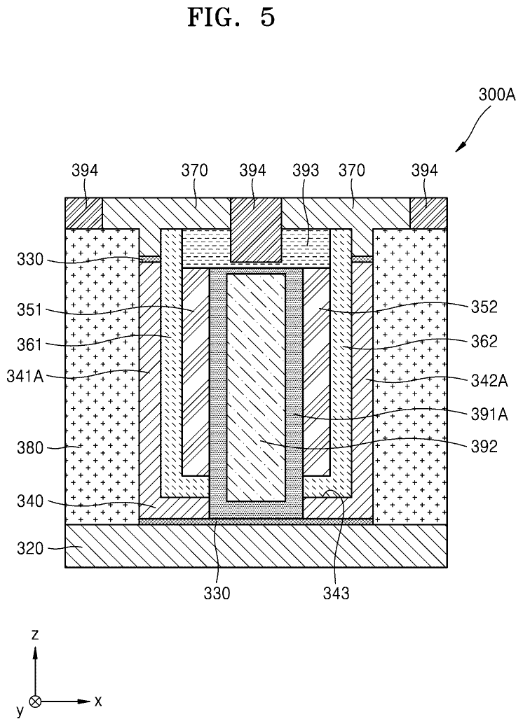

FIG. 5 illustrates a semiconductor device according to another embodiment.

In FIG. 5, components using the same reference numerals as those of FIG. 4 have substantially the same configuration and effect as those described with reference to FIG. 4, and thus a detailed description thereof is omitted.

When compared to FIG. 4, the shape of the oxide channel of FIG. 5 may be different from that of FIG. 4. In a semiconductor device 300A, an oxide semiconductor layer may include a first oxide semiconductor layer 341A and a second oxide semiconductor layer 342A. The first oxide semiconductor layer 341A may have an L cross-sectional shape, and the second oxide semiconductor layer 342A may have a shape symmetrical to the first oxide semiconductor layer 341A in the z direction. The first oxide semiconductor layer 341A and the second oxide semiconductor layer 342A are separated from each other. An insulating liner 391A may extend between the first oxide semiconductor layer 341A and the second oxide semiconductor layer 342A.

The first oxide semiconductor layer 341 and the second oxide semiconductor layer 342 may be positioned so that the length directions thereof are arranged in a direction (z direction) perpendicular to the substrate (not illustrated).

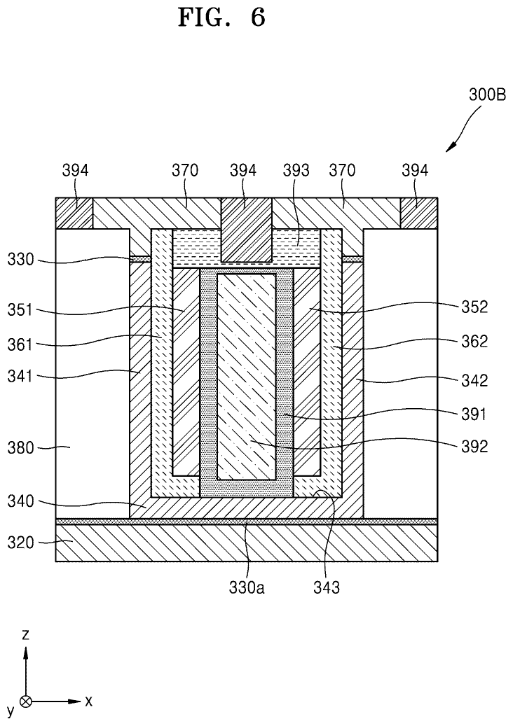

FIG. 6 illustrates a modified example of a metal oxide layer in the semiconductor device of FIG. 4.

As compared to FIG. 5, in FIG. 6, a metal oxide layer 330a may be provided over the entire first electrode 320. Here, the first electrode 320 may be formed as a bit line, and the metal oxide layer 330a may be provided along the first electrode 320.

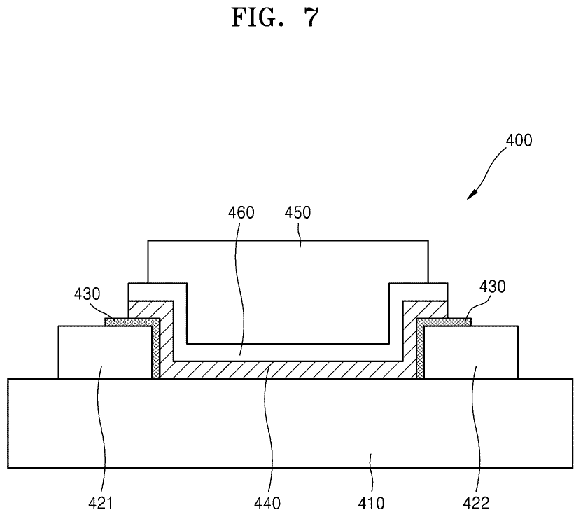

FIG. 7 illustrates a semiconductor device according to another embodiment.

A semiconductor device 400 may include a substrate 410, a first electrode 421 and a second electrode 422 spaced from each other on the substrate 410, an oxide semiconductor layer 440 provided on the substrate 410, a gate electrode 450 spaced apart from the oxide semiconductor layer 440, and a gate insulating layer 460 arranged between the oxide semiconductor layer 440 and the gate electrode 450. The oxide semiconductor layer 440 may extend to upper portions of the first electrode 421 and the second electrode 422.

A metal oxide layer 430 may be provided at least one of between the first electrode 421 and the oxide semiconductor layer 440 and between the second electrode 422 and the oxide semiconductor layer 440. In FIG. 7, the metal oxide layers 430 are provided on both sides, respectively. The metal oxide layer 430 may be provided at each of an interface between the first electrode 421 and the oxide semiconductor layer 440 and an interface between the second electrode 422 and the oxide semiconductor layer 440. The semiconductor device 400 may be applied to a transistor having a planar channel structure.

Since the metal oxide layer 430 and the oxide semiconductor layer 440 have substantially the same configuration and effect as those of the metal oxide layer 130 and the oxide semiconductor layer 140 described above with reference to FIG. 1, a detailed description thereof is omitted herein.

The gate electrode 450 may be spaced apart from the oxide semiconductor layer 440. The gate insulating layer 460 may be arranged between the oxide semiconductor layer 440 and the gate electrode 450. The gate electrode 450 may include at least one of a metal, a metal nitride, and a transparent conductive oxide (TCO). The gate insulating layer 460 may include an oxide including at least one of hafnium (Hf), zirconium (Zr), aluminum (Al), and silicon (Si). When the semiconductor device 400 is a component of a memory cell, the gate electrode 450 may be a partial region of a word line.

The first electrode 421 and the second electrode 422 may be arranged on the bottom surface of the oxide semiconductor layer 440, and the gate electrode 450 may be arranged on the top surface of the oxide semiconductor layer 440. However, embodiments are not limited thereto. The first electrode 421, the second electrode 422, and the gate electrode 450 may be arranged on the same surface of that of the oxide semiconductor layer 440. The first electrode 421 may be a source electrode, and the second electrode 422 may be a drain electrode. The first electrode 421 and the second electrode 422 may be configured in the same materials as the materials of the first electrode 120 and the second electrode 170 described with reference to FIG. 1.

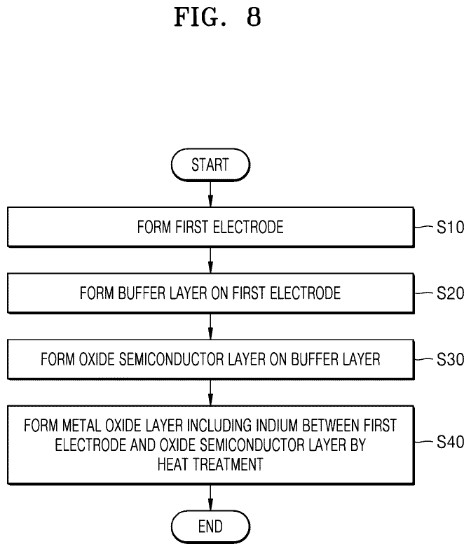

FIG. 8 is a flowchart illustrating a method of manufacturing a semiconductor device according to an embodiment. In describing the manufacturing method, the order of each operation does not limit the order of the manufacturing process.

Referring to FIG. 8, a first electrode including at least one metal of Ru and W is formed on a substrate (S10). A buffer layer including indium is formed on the first electrode (S20). The buffer layer may be an oxide including In. For example, the buffer layer including indium may include indium oxide (InO) or indium tin oxide (ITO). The buffer layer may have a thickness greater than 3 nm and less than or equal to 7 nm. The buffer layer may be formed by a physical vapor deposition method, a chemical vapor deposition method, or an atomic layer deposition (ALD) method. An oxide semiconductor layer may be formed on the buffer layer (S30). The oxide semiconductor layer may include at least one of indium (In), gallium (Ga), zinc (Zn), tungsten (W), tin (Sn), and hafnium (Hf). The oxide semiconductor layer may be formed by an atomic layer deposition method.

In addition, heat treatment may be performed. By the heat treatment, a metal oxide layer including at least one metal of In, Ru, and W may be formed between the first electrode and the oxide semiconductor layer (S40). For example, the metal oxide layer may be formed by diffusing the metal elements of W and/or Ru of the first electrode and the indium of the buffer layer during the heat treatment process. Alternatively, the metal oxide layer may be formed by diffusing the W and/or Ru metal of the first electrode into the buffer layer during the heat treatment process. Diffusion positions of W and/or Ru metals may be controlled according to the thickness or composition of the buffer layer.

The heat treatment may be performed within a range in which the metal oxide layer is appropriately controlled to have a desired content of In, W, and/or Ru content in consideration of the thickness of the buffer layer, the diffusion rate of indium, the diffusion rate of W or Ru, and the like. For example, the heat treatment may be performed at a temperature of 350° C. or higher, 400° C. or higher, or 450° C. or higher, and 600° C. or lower, or 550° C. or lower. The metal oxide layer may include a local region in which the content of W and/or Ru metals is 20 at % or less, and the sum of the content of W and/or Ru metals and the content of indium is 60 at % or more.

The buffer layer may partially remain or may not partially remain after heat treatment.

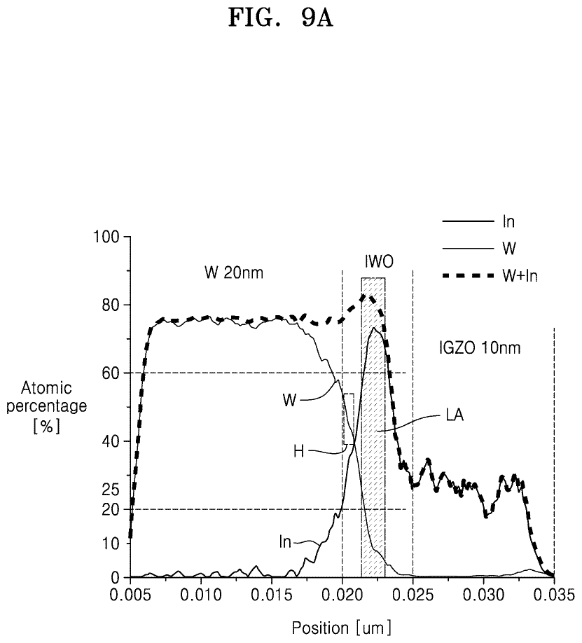

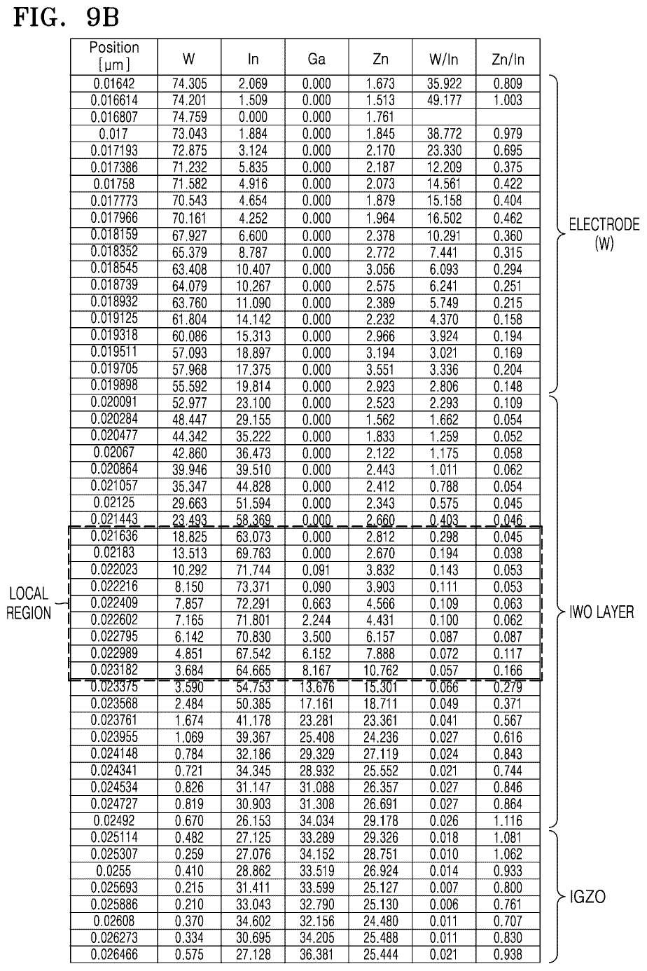

FIGS. 9A and 9B show a composition analysis result according to a thickness direction position of a semiconductor device according to Examples using an energy dispersive X-ray spectroscopy (EDS) analysis method. A semiconductor device according to an embodiment was manufactured by sequentially forming an In oxide buffer layer of 5 nm, an IGZO (In:Ga:Zn=about 1:1:1) oxide semiconductor layer of 10 nm, and an Hf oxide gate insulating layer on a W electrode of 20 nm, and forming a metal oxide layer including In and W between the W electrode and the IGZO oxide semiconductor layer by heat treatment at 400° C. FIG. 9A is a graph showing compositions of W and In according to positions of semiconductor devices in a thickness direction according to Examples, and FIG. 9B is a table illustrating compositions of W, In, Ga, and Zn according to positions of semiconductor devices in a thickness direction according to Examples. The data from the top to the bottom of the table of FIG. 9B shows the content for each position of the W electrode, the IWO metal oxide layer, and the IGZO oxide semiconductor.

Referring to FIGS. 9A and 9B, a semiconductor device according to Examples includes a local region LA in which indium is intensively included between an electrode and an oxide semiconductor layer. In addition, in the semiconductor device according to the Examples, the content of W, which is a metal element, is very small in the local region LA where indium is intensively included. Referring to FIGS. 9A and 9B, the metal oxide layer of the semiconductor device according to Examples may include a local region LA in which a content of W is 20 at % or less and a sum of a content of W and a content of In is 60 at % or more. The local region LA may be located in a region of 20% to 80% of a thickness of the metal oxide layer from a boundary between the first electrode and the metal oxide layer. In addition, a region in which an indium content of the metal oxide layer is higher than the W metal content may be located in a region of 20% or more of a thickness of the metal oxide layer from a boundary between the electrode and the metal oxide layer.

In the metal oxide layer of the semiconductor device according to Examples, a region H in which the W content is higher than the In content may be located in a region of 30% or less or 20% or less of the thickness of the metal oxide layer from an interface between the electrode and the metal oxide layer. The local region LA and the region H may be positioned not to overlap each other.

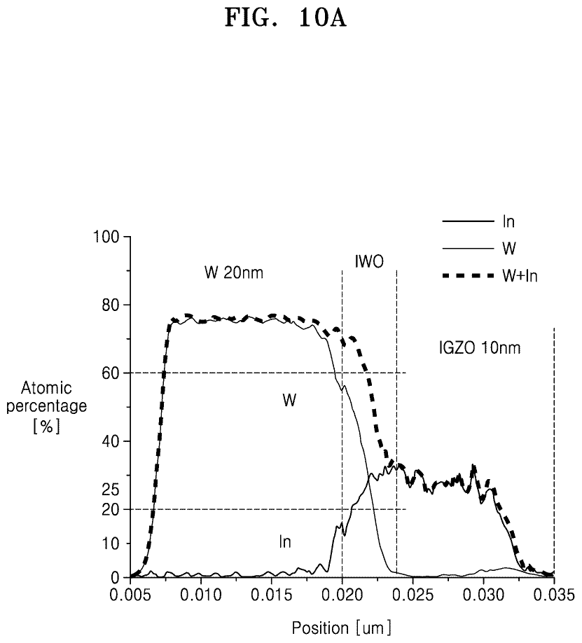

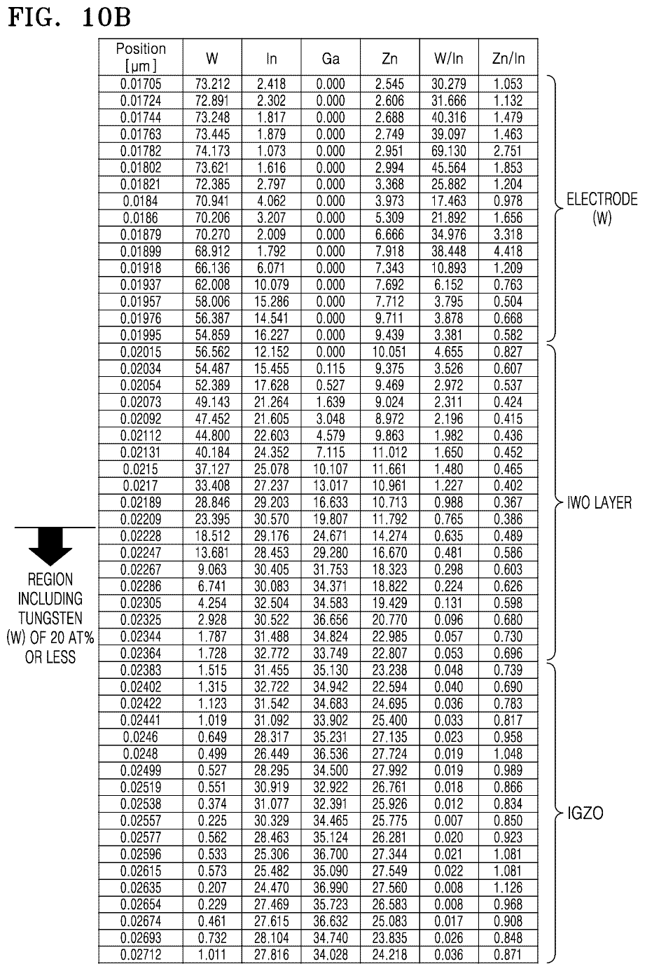

FIGS. 10A and 10B respectively show, as a graph and a table, a composition analysis result according to a thickness direction position of a semiconductor device according to a comparative example using an energy dispersive X-ray spectroscopy (EDS) analysis method. A semiconductor device according to a comparative example was manufactured by sequentially forming an In oxide buffer layer of 3 nm, an IGZO (In:Ga:Zn=about 1:1:1) oxide semiconductor layer of 10 nm, and an Hf oxide gate insulating layer on a W electrode of 20 nm, and forming an oxide layer including In and W between the W electrode and the IGZO oxide semiconductor layer by heat treatment at 400° C. Referring to FIGS. 10A and 10B, in a semiconductor device according to a comparative example, a region including indium intensively is not substantially present between an electrode and an oxide semiconductor layer, and W which is a metal element is relatively large. In the comparative example, there is no local region where the content of W is 20 at % or less, and the sum of the content of W and In is 60 at % or more.

Next, an operational effect of the semiconductor device according to Examples is described.

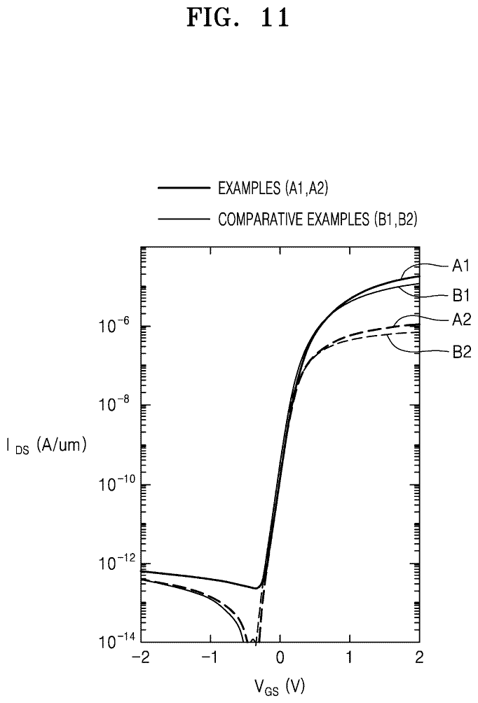

FIG. 11 illustrates voltage-current (V-I) graphs of a semiconductor device according to Comparative Examples and a semiconductor device according to Examples.

In the graph, A1 represents the case where V_{DS} (=1 V) is applied to the drain electrode of the semiconductor device of the Example A1, and A2 represents the case where V_{DS} (=0.05 V) is applied to the semiconductor device of the Example A2. B1 represents the case where V_{DS} (=1 V) is applied to the drain electrode of the semiconductor device of the comparative example, and B2 represents the case where V_{DS} (=0.05 V) is applied to the semiconductor device of the comparative example.

When V_{DS}=1 V, comparing Examples and Comparative Examples, the current I_{DS} of the Examples is higher than the current I_{DS} of Comparative Examples, and when V_{DS}=0.05 V, comparing Embodiments and Comparative Examples, the current I_{DS} of the Examples is higher than the current I_{DS} of Comparative Examples.

The following shows the threshold voltage Vₜₕ, the on-current (Iₒₙ), and the contact resistor (ρ_cont) of Examples and Comparative Examples.

TABLE 1

| | Vₜₕ (V) | Iₒₙ (μA/μm) | ρ_cont (Ω · cm²) |
|---|---|---|---|
| Comparative | −0.2 | 3.5 | 4.2E−05 |
| Example (B1) | | | |
| Example (A1) | −0.1 | 3.8 | 1.0E−06 |

Table 1 shows that the semiconductor device according to Example A1 has a lower contact resistance than the semiconductor device of Comparative Example B1. As in the semiconductor device according to the Examples, when the content of In is high between the electrode and the oxide semiconductor layer and the content of W is low, a local region where the content of W is 20 at % or less, and the sum of the content of W and the content of In is 60 at % or more, may be included, and thus the contact resistance may be low.

As described above, in a semiconductor device according to the Examples, the metal oxide layer includes the local region LA, thereby lowering contact resistance. The semiconductor device according to the Examples may reduce contact resistance by adjusting the indium content and the metal content of the metal oxide layer.

Since oxide semiconductors have a high bandgap compared to silicon, the oxide semiconductors may be applied to DRAM cell transistor channels requiring relatively low off-current. However, oxide semiconductor channels have high contact resistance compared to silicon channels, so off-current may be low, but on-current may be relatively small. The semiconductor device according to the Examples may reduce contact resistance, increase on-current, and be applied to various electronic devices by adjusting the indium content of the metal oxide layer by compensating for the disadvantages of the oxide semiconductor channel.

Recently, silicon-based memory or logic devices have reached the limit of high integration and may require channel lengths of tens or several nanometers, making it very important to reduce off-currents. In addition, it may be advantageous to improve subthreshold swing (SS) and on/off ratio as characteristics required to clarify the distinction between on/off states. Oxide semiconductor devices used as large-area display driving devices have very excellent required characteristics (low off-current, low SS, and high on/off ratio). Therefore, recently, the oxide semiconductor devices having such an advantage may be applied to memory or logic devices.

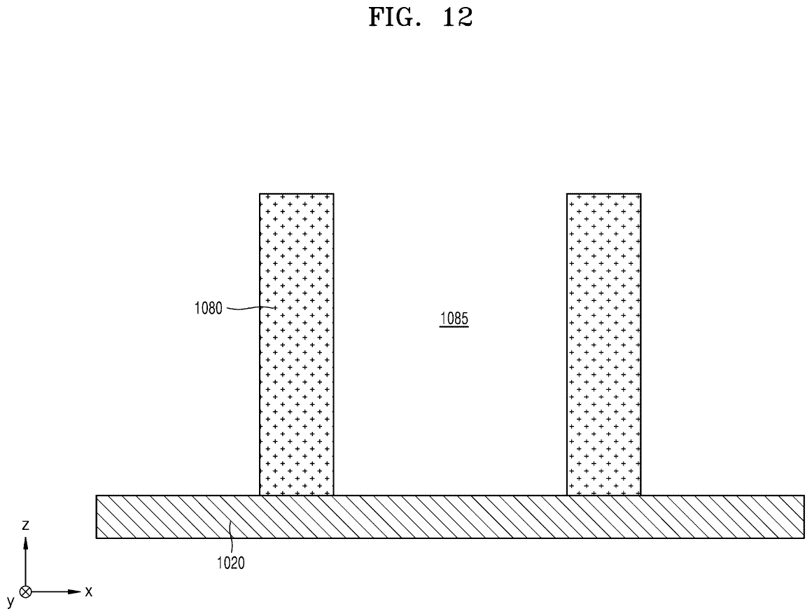

Next, a method of manufacturing a semiconductor device according to an embodiment will be described with reference to FIGS. 12 to 21.

Referring to FIG. 12, a plurality of mold insulating layers 1080 extending in the second horizontal direction y may be deposited on the first electrode 1020 extending in the first horizontal direction x. The mold insulating layers 1080 may be stacked in the vertical direction z until the mold insulating layers 1080 have a desired and/or alternatively predetermined height. The plurality of mold insulating layers 1080 and the first electrode 1020 may form openings 1085.

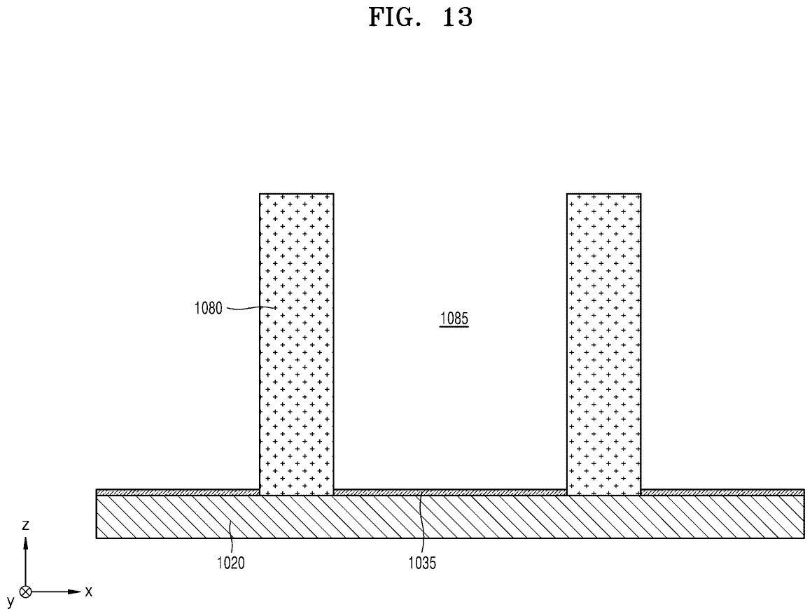

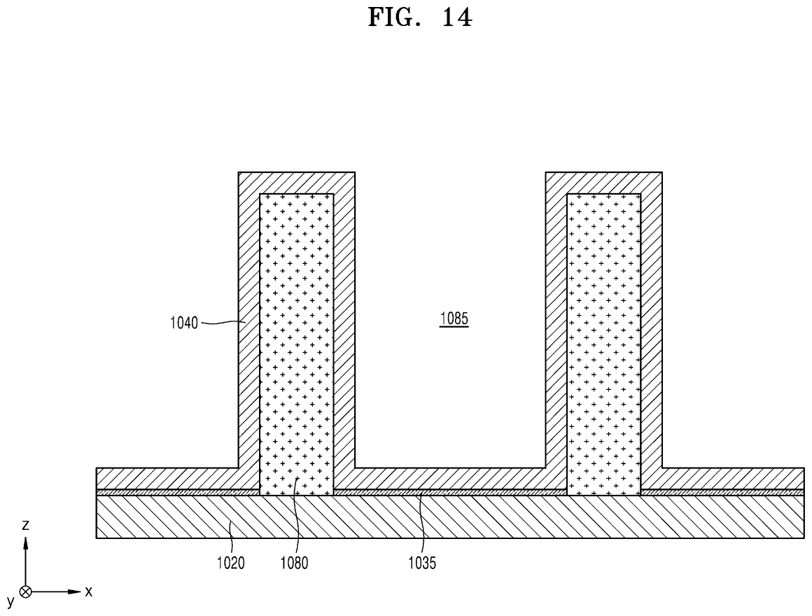

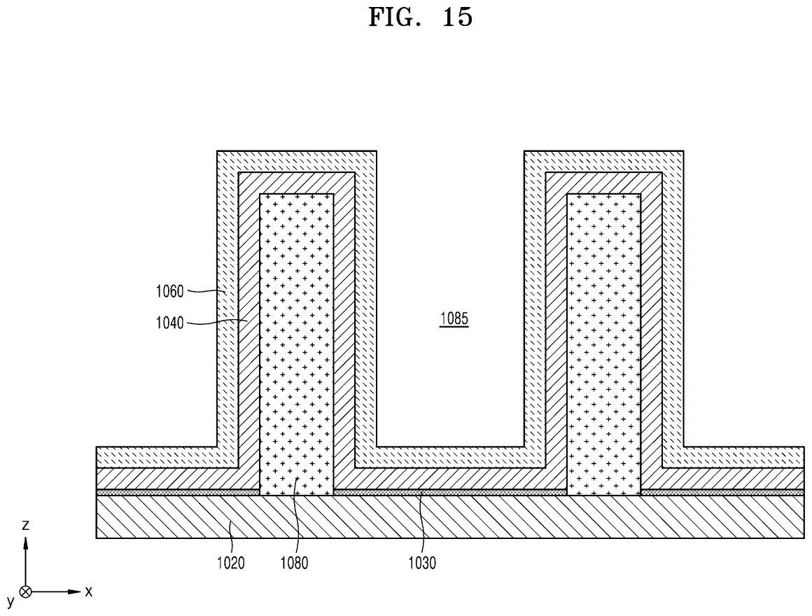

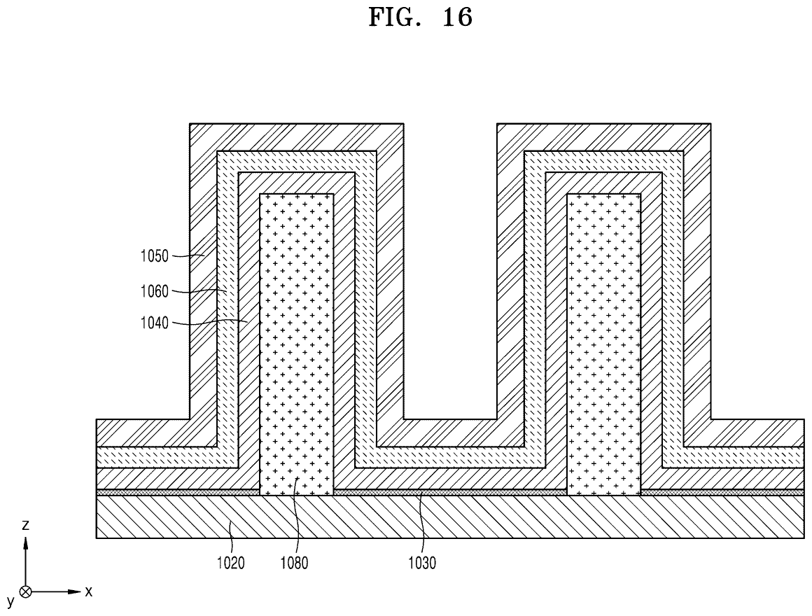

Referring to FIG. 13, a buffer layer 1035 may be formed on the first electrode 1020. The buffer layer 1035 may include InO or ITO. Referring to FIG. 14, an oxide semiconductor layer 1040 may be deposited on the buffer layer 030 and the mold insulating layers 1080. The oxide semiconductor layer 1040 may be deposited by, for example, an ALD method. The oxide semiconductor layer 1040 may have a U-shaped cross-sectional shape. Referring to FIG. 15, the metal oxide layer 1030 including indium and a metal may be formed by oxidation of the first electrode 1020 and action of the buffer layer 1035 during the deposition process of the oxide semiconductor layer 1040. The metal oxide layer 1030 may include a local region where the indium content is 10 at % or less and the sum of the indium content and the metal content is in a range of 25 at % to 30 at %. In addition, a gate insulating layer 1060 may be deposited on the oxide semiconductor layer 1040. In FIG. 15, it is assumed that the buffer layer 1035 does not remain. Referring to FIG. 16, a gate electrode 1050 may be deposited on the gate insulating layer 1060. The gate insulating layer 1060 may include an oxide including at least one of hafnium (Hf), zirconium (Zr), aluminum (Al), and silicon (Si).

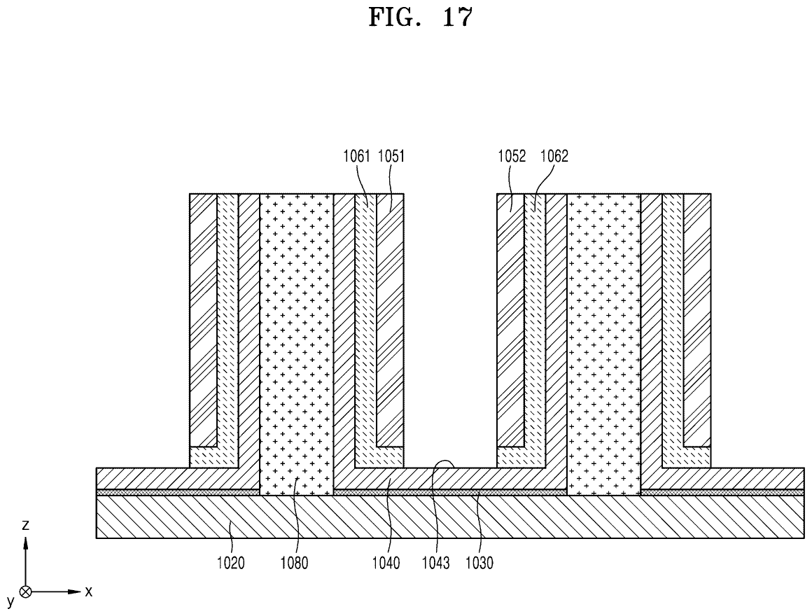

Referring to FIG. 17, anisotropic etching is performed on the gate electrode 1050 of the structure shown in FIG. 16, so that the bottom portion 1043 of the oxide semiconductor layer 1040 may be exposed. Accordingly, the gate electrode 1050 may be separated into a first gate electrode 1051 and a second gate electrode 1052, and the gate insulating layer 1060 may be separated into a first gate insulating layer 1061 and a second gate insulating layer 1062. In addition, in the upper direction of the mold insulating layer 1080, the gate electrode 1050, the gate insulating layer 1060, and the oxide semiconductor layer 1040 may be etched to expose the upper surfaces of the mold insulating layers 1080. The upper surfaces of the mold insulating layers 1080, the upper surfaces of the first gate electrode 1051 and the second gate electrode 1052, and the upper surfaces of the first gate insulating layer 1061 and the second gate insulating layer 1062 may have a same level.

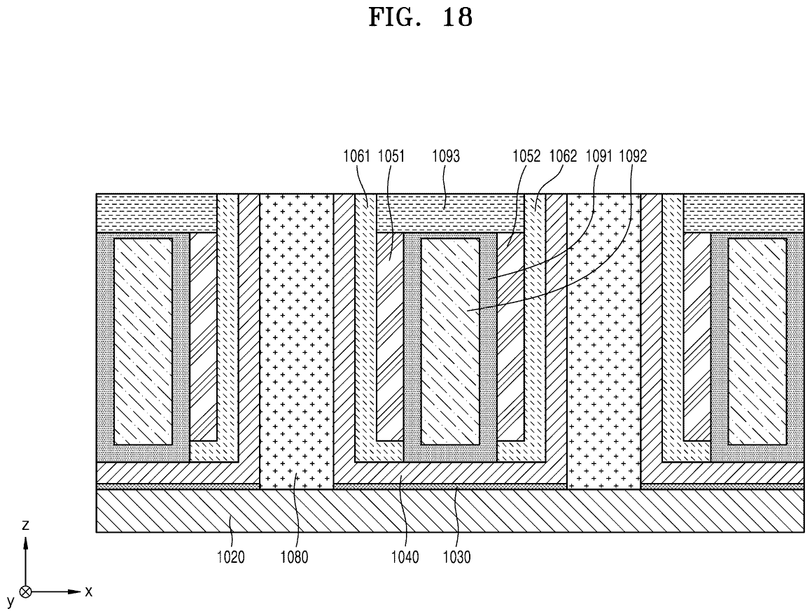

Referring to FIG. 18, when the gate electrode 1050 is etched once more, upper surface levels of the first gate electrode 1051 and the second gate electrode 1052 may be lower than upper surface levels of the mold insulating layers 1080. An insulating liner 1091 may be deposited from a surface of the bottom portion of the oxide semiconductor layer 1040 and deposited up to the upper surface levels of the first gate electrode 1051 and/or the second gate electrode 1052. A buried insulating layer 1092 may be filled inside the insulating liner 1091. The insulating liner 1091 and the buried insulating layer 1092 may not be distinguished from each other. An upper insulating layer 109 may be deposited on the upper surfaces of the first gate electrode 1051 and/or the second gate electrode 1052 and the upper surface of the insulating liner 1091. A surface level of the upper insulating layer 1093 may coincide with an upper surface level of the mold insulating layer 1080, an upper surface level of the oxide semiconductor layer 1040, upper surface levels of the first gate electrode 1051 and the second gate electrode 1052, and upper surface levels of the first gate insulating layer 1061 and the second gate insulating layer 1062.

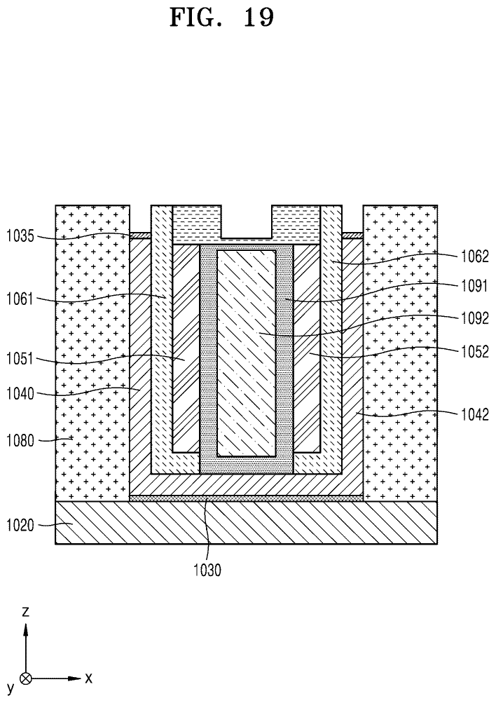

FIG. 19 illustrates only a portion corresponding to one pixel in FIG. 18 for convenience. Referring to FIG. 19, an upper portion of the oxide semiconductor layer 1040 may be partially etched, and a buffer layer 1035 may be deposited on the remaining upper portion of the oxide semiconductor layer 1040.

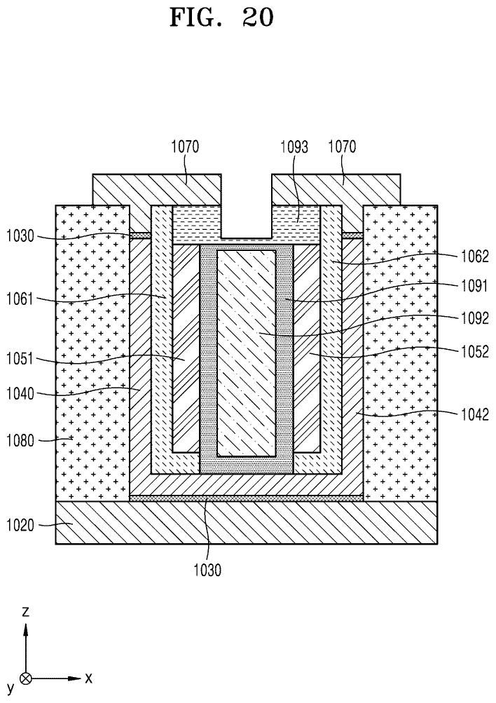

Referring to FIG. 20, a second electrode 1070 may be deposited on the buffer layer 1035. In this case, as described above, a metal oxide layer 1030 including indium and a metal may be formed between the oxide semiconductor layer 1040 and the second electrode 1070. Meanwhile, after depositing the second electrode 1070, a central portion of the second electrode 1070 and an upper portion of the upper insulating layer 1093 may be partially etched.

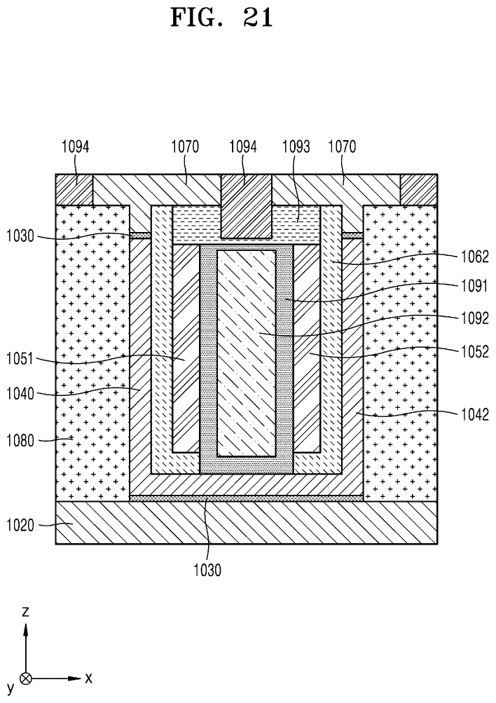

Referring to FIG. 21, a second electrode insulating layer 1094 may be deposited between the second electrode 1070 and the second electrode 1070 and on some parts of an upper portion of the upper insulating layer 1093. An upper surface level of the second electrode insulating layer 1094 and a surface level of the second electrode 1070 may coincide with each other.

The method of manufacturing a semiconductor device according to an embodiment may reduce contact resistance generated at an interface between the electrode and the oxide semiconductor layer and increase an on-current by adjusting an indium content and a metal content of the metal oxide layer formed between the electrode and the oxide semiconductor layer.

The semiconductor device according to an embodiment is suitable for application to an integrated circuit device having a high degree of integration because it has a micro size and excellent electrical performance.

The semiconductor device according to an embodiment may constitute a transistor applied for a digital circuit or an analog circuit. In some embodiments, an example semiconductor device may be used as a high voltage transistor or a low voltage transistor. For example, a semiconductor device of an embodiment may constitute a high voltage transistor that constitutes a peripheral circuit of a flash memory device and an electrically erasable and programmable read only memory (EEPROM) device, which is a nonvolatile memory device operating at a high voltage. Alternatively, an embodiment may constitute a transistor included in an IC chip for a liquid crystal display (LCD), an IC chip used in an LED display device, or a micro LED display device, and the like. Alternatively, a semiconductor device according to an embodiment may be applied to a DRAM.

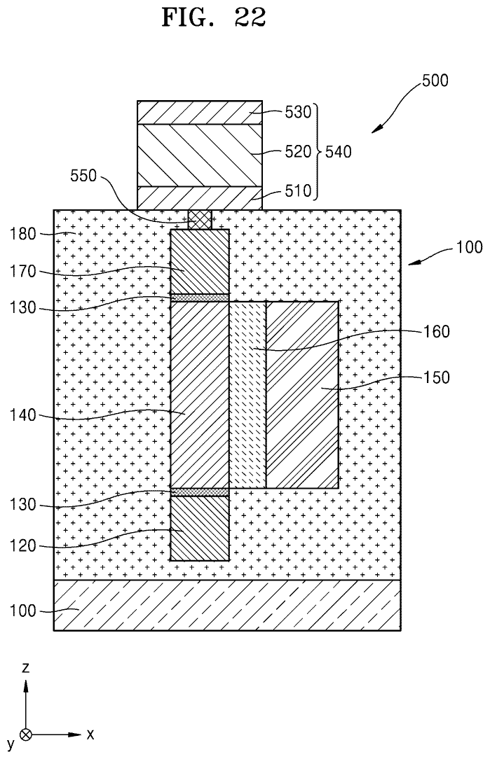

FIG. 22 illustrates an example in which a semiconductor device according to an embodiment is applied to a DRAM.

An electronic device 500 may include a semiconductor device 100 and a capacitor 540 electrically connected to the semiconductor device 100. For simplicity of description, substantially the same description as that described with reference to FIG. 1 may not be described with respect to the semiconductor device 100.

The capacitor 540 may include a third electrode 510, a dielectric layer 520, and a fourth electrode 530. The third electrode 510 and the fourth electrode 530 may be selected to secure conductivity as electrodes and to maintain stable capacitance performance even after a high-temperature process in the manufacturing process of the capacitor 540. In an example, the third electrode 510 and the fourth electrode 530 may include metal, metal nitride, metal oxide, or a combination thereof. For example, the third electrode 510 and the fourth electrode 530 may include TiN, NbN, MON, CON, TaN, W, Ru, RuO₂, SrRuO₃, Ir, IrO₂, Pt, PtO, SRO(SrRuO₃), BSRO((Ba, Sr)RuO₃), CRO(CaRuO₃), LSCO((La, Sr)CoO₃), or a combination thereof.

The dielectric layer 520 may include at least one of a dielectric material, a high-k material, and a ferroelectric material. The dielectric material may include, for example, silicon oxide. The high-k material refers to a material having a dielectric constant higher than that of silicon oxide. The high-k material may be a metal oxide including at least one selected from Ca, Sr, Ba, Sc, Y, La, Ti, Hf, Zr, Nb, Ta, Ce, Pr, Nd, Gd, Dy, Yb, and Lu. For example, the high-k material may include at least one of hafnium oxide, zirconium oxide, cerium oxide, lanthanum oxide, tantalum oxide, and titanium oxide. The ferroelectric material may include a ferroelectric material having ferroelectricity in which internal electric dipole moments are aligned to maintain spontaneous polarization even when an electric field is not applied from the outside. When an electric field is not applied to the ferroelectric, the ferroelectric has a random polarization direction, but when an electric field is applied, the size of the polarization increases such that the direction of the polarization is the same as the direction of an external electric field. The ferroelectric has the characteristic that polarization aligned in one direction maintains its state even when an electric field is formed and disappeared. The ferroelectric material may include at least one of a perovskite structure, a fluorite structure, and a wurtzite structure.

A contact 550 may be provided between the second electrode 170 and the third electrode 510. The contact 550 may electrically connect the second electrode 170 and the third electrode 510 to each other. The contact 550 may include a conductive material (e.g., metal).

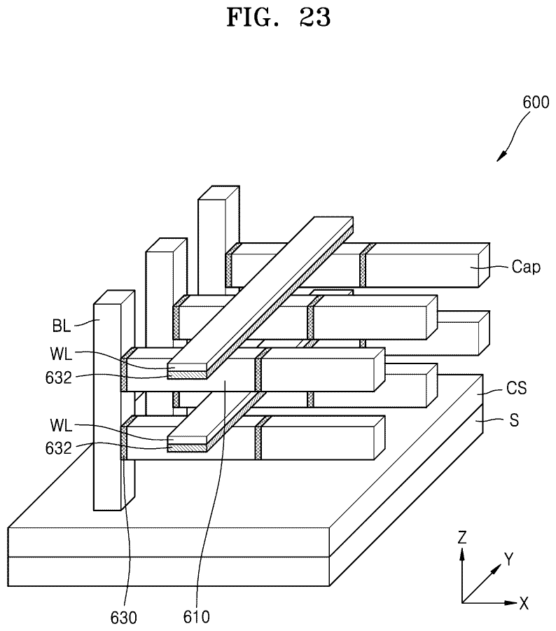

FIG. 23 is a schematic perspective view illustrating an example in which a semiconductor device according to an embodiment is applied to a vertically stacked memory device 600. Referring to FIG. 23, the vertically stacked memory device 600 may include a plurality of bit lines BL extending in a first direction (e.g., the Z direction), a plurality of oxide semiconductor layers 610 respectively connected to the plurality of bit lines BL and extending in a second direction (e.g., the X direction) vertically intersecting the first direction, a plurality of capacitors Cap electrically connected to the plurality of oxide semiconductor layers 610, respectively, and a plurality of word lines WL extending to cross the plurality of oxide semiconductor layers 610 in a third direction (e.g., the Y direction) vertically intersecting the first direction and the second direction. The word line WL may correspond to a gate electrode. A gate insulating layer 632 may be provided between the oxide semiconductor layer 610 and the word line WL. A metal oxide layer 630 may be provided between the oxide semiconductor layer 610 and the bit line BL. In addition, another metal oxide layer 630 may be provided between the oxide semiconductor layer 610 and the capacitor Cap. Since the metal oxide layer 630 is substantially the same as the metal oxide layer 130 described with reference to FIG. 1, a detailed description thereof is omitted. Although FIG. 23 illustrates that each of the plurality of word lines WL crosses over the corresponding oxide semiconductor layer 610 among the plurality of oxide semiconductor layers 610, embodiments are not limited thereto and each of the plurality of word lines WL may cross under the corresponding oxide semiconductor layer 610.

In addition, the vertically stacked memory device 600 may further include a growth substrate S and a driving circuit board CS provided on the growth substrate S. The driving circuit board CS may include circuits for performing an input/output operation of receiving data from the outside or outputting data to the outside by being connected to an external circuit, and an operation of recording data on the capacitor Cap or reading data recorded on the capacitor Cap.

The plurality of bit lines BL may be provided on the driving circuit board CS to be erected perpendicularly to the upper surface of the driving circuit board CS. Although FIG. 23 shows that only three bit lines BL are arranged in a line at intervals in the third direction for convenience, a larger number of bit lines BL may be arranged in two dimensions in reality. For example, the plurality of bit lines BL extending in the vertical direction, that is, in the first direction, may be two-dimensionally arranged on the driving circuit board CS at regular intervals in the second and third directions. The plurality of bit lines BL may be arranged parallel to each other.

The plurality of oxide semiconductor layers 610 connected to one corresponding bit line BL among the plurality of bit lines BL may be arranged at intervals in the first direction. Although only two oxide semiconductor layers 610 are illustrated for one bit line BL for convenience in FIG. 23, a large number of oxide semiconductor layers 610 may be arranged at intervals in the first direction. In addition, the plurality of oxide semiconductor layers 610 may be arranged parallel to each other at regular intervals in the third direction within the same layer. The plurality of oxide semiconductor layers 610 arranged on the same layer may be connected to one corresponding bit line different from each other among the plurality of bit lines BL. Like the plurality of bit lines BL, the plurality of oxide semiconductor layers 610 may be two-dimensionally arranged at regular intervals in the second direction and the third direction. Each of the plurality of oxide semiconductor layers 610 may extend in the second direction. A first end of each of the plurality of oxide semiconductor layers 610 may be electrically connected to one corresponding bit line among the plurality of bit lines BL. The bit line BL may correspond to a first electrode or a source electrode of a semiconductor device. A second end of each of the plurality of oxide semiconductor layers 610, opposite to the first end in the second direction, may be electrically connected to a corresponding capacitor Cap of the plurality of capacitors Cap.

Although each of the capacitors Cap is illustrated as one block for convenience in FIG. 23, in fact, each of the capacitors Cap may include a first electrode, a second electrode, and a dielectric layer arranged between the first electrode and the second electrode. The first electrode of the capacitor Cap may be electrically connected to the second end of the corresponding oxide semiconductor layer 610 among the plurality of oxide semiconductor layers 610. Therefore, one oxide semiconductor layer 610 and one capacitor Cap may be connected to each other on a one-to-one basis. Although not shown, the second electrode of the capacitor Cap may be connected to a ground line of the vertically stacked memory device.

A gate insulating layer 632 may be arranged between the oxide semiconductor layer 610 and the word line WL. Although not shown for convenience in FIG. 23, the vertically stacked memory device 600 may further include an insulator material filled in a space between the plurality of bit lines BL, between the plurality of oxide semiconductor layers 610, and between the plurality of word lines WL.

One oxide semiconductor layer 610 may form one oxide semiconductor transistor together with one word line WL, one bit line BL, and a first electrode of one capacitor Cap, which correspond to the one oxide semiconductor layer 610. The first electrode of the oxide semiconductor transistor may be a component of the bit line BL, the gate electrode may be a component of the word line WL, and the second electrode may be used in common with the first electrode of the capacitor Cap or may be configured as a separate electrode of the transistor. However, embodiments are not limited thereto. The first electrode, the gate electrode, and the second electrode may be provided as separate layers, and may be electrically connected to electrodes of the bit line BL, the word line WL, and the capacitor Cap.

It has been described that the word line WL may serve as a gate electrode of the oxide semiconductor transistor, and when a gate signal greater than or equal to a threshold voltage is applied to the word line WL, a current may flow along the oxide semiconductor layer 610. Then, the bit line BL and the capacitor Cap corresponding to each other may be electrically connected to each other to write data on the capacitor Cap or read data written on the capacitor Cap.

Therefore, one oxide semiconductor layer 610 and one capacitor Cap corresponding thereto may form one memory cell. The vertically stacked memory device 600 according to an embodiment may include a plurality of memory cells two-dimensionally arranged on one layer. In addition, the vertically stacked memory device 600 may have a structure in which multiple layers including multiple memory cells arranged in two dimensions are stacked. Accordingly, since the degree of integration of memory cells is high, the recording capacity of the vertically stacked memory device 600 may be improved.

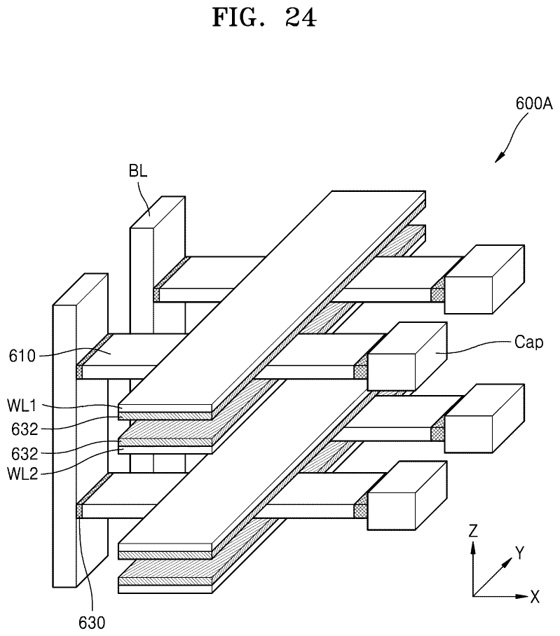

FIG. 24 is a perspective view illustrating a schematic structure of a vertically stacked memory device 600A according to another embodiment. Referring to FIGS. 23 and 24, the vertically stacked memory device 600A of FIG. 24 may have a double gate structure. For example, the vertically stacked memory device 600A may include a first word line WL1 extending in the third direction to cross over multiple oxide semiconductor layers 610 arranged on the same layer and a second word line WL2 extending in the third direction to cross under multiple oxide semiconductor layers 610 arranged on the same layer. The first word line WL1 and the second word line WL2 may be spaced apart from each other in the first direction with the corresponding oxide semiconductor layer 610 therebetween and may be arranged to face each other in parallel. In other words, each of the plurality of word lines WL shown in FIG. 24 may include the first word line WL1 and the second word line WL2 spaced apart from each other in the first direction with a corresponding oxide semiconductor layer 610 among the multiple oxide semiconductor layers 610 therebetween and arranged to face each other in parallel.

One oxide semiconductor layer 610 may form one oxide semiconductor transistor together with the first word line WL1 and the second word line WL2, which correspond to the one oxide semiconductor layer 610. The operation of one oxide semiconductor transistor may be controlled together by the first word line WL1 arranged on the oxide semiconductor layer 610 and the second word line WL2 arranged under the oxide semiconductor layer 10. Therefore, the driving reliability of the oxide semiconductor transistor may be improved. Other components of the vertically stacked memory device 600A illustrated in FIG. 24 may be the same as those of the vertically stacked memory device 600 illustrated in FIG. 23, and thus a detailed description thereof is omitted.

In FIGS. 23 and 24, the bit lines BL are arranged vertically on the upper surface of the driving circuit board CS and the word lines WL are arranged horizontally on the upper surface of the driving circuit board CS, but embodiments are not limited thereto. The bit lines BL are arranged horizontally on the upper surface of the driving circuit board CS and the word lines WL are arranged vertically on the upper surface of the driving circuit board CS. That is, the oxide semiconductor layer 610 and the capacitor Cap may be sequentially arranged from the driving circuit board CS.

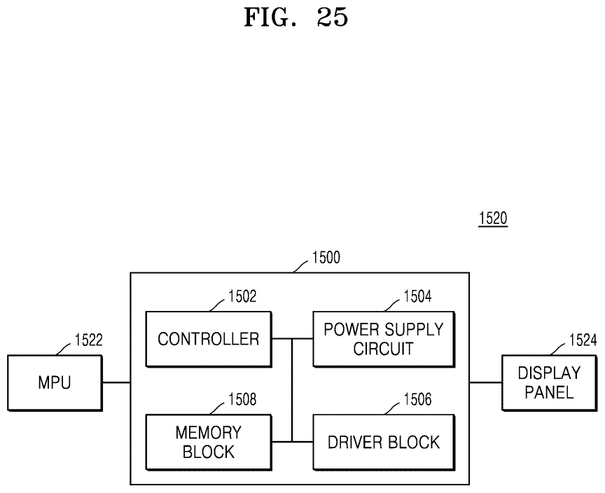

FIG. 25 is a schematic block diagram of a display driver IC (DDI) 1500 including a semiconductor device and a display device 1520 including the DDI 1500 according to an embodiment.

Referring to FIG. 25, the DDI 1500 may include a controller 1502, a power supply circuit 1504, a driver block 1506, and a memory block 1508. The controller 1502 receives and decodes a command applied from a main processing unit (MPU) 1522, and the controller 1502 may control each block of the DDI 1500 to implement an operation according to the command. The power supply circuit 1504 generates a driving voltage in response to the control of the controller 1502. The driver block 1506 drives a display panel 1524 by using the driving voltage generated by the power supply circuit 1504 in response to the control of the controller 1502. The display panel 1524 may be a liquid crystal display panel or a micro LED device. The memory block 1508 is a block that temporarily stores commands input to the controller 1502 or control signals output from the controller 1502, or stores necessary data, and may include memories such as RAM and ROM. The power supply circuit 1504 and the driver block 1506 may include the semiconductor device according to the embodiments described above.

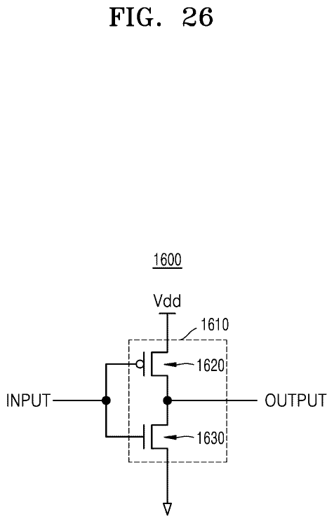

FIG. 26 is a circuit diagram of a CMOS inverter according to an embodiment.

The CMOS inverter 1600 includes a CMOS transistor 1610. The CMOS transistor 1610 includes a PMOS transistor 1620 and an NMOS transistor 1630 connected between a power terminal Vdd and the ground terminal. The CMOS transistor 1610 may include the semiconductor device according to the embodiments described above.

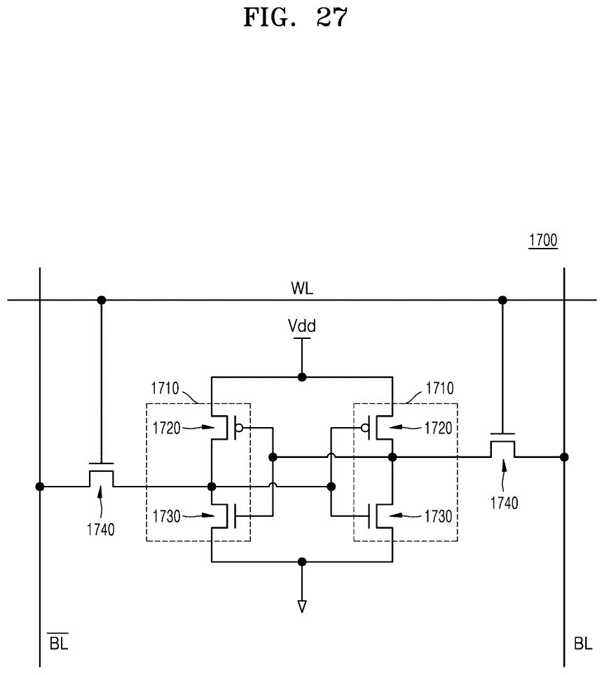

FIG. 27 is a circuit diagram of a CMOS SRAM device 1700 according to an embodiment.

The CMOS SRAM device 1700 includes a pair of driving transistors 1710. Each of the pair of driving transistors 1710 includes a PMOS transistor 1720 and an NMOS transistor 1730 connected between the power terminal Vdd and the ground terminal. The CMOS SRAM device 1700 may further include a pair of transfer transistors 1740. A source of the transfer transistor 1740 is cross-connected to a common node of the PMOS transistor 1720 and the NMOS transistor 1730 constituting the driving transistor 1710. The power terminal Vdd is connected to a source of the PMOS transistor 1720, and the ground terminal is connected to a source of the NMOS transistor 1730. A word line WL may be connected to the gates of the pair of transfer transistors 1740, and a bit line BL and an inverted bit line may be connected to the drains of the pair of transfer transistors 740, respectively.

At least one of the driving transistor 1710 and the transfer transistor 1740 of the CMOS SRAM device 1700 may include the semiconductor device according to the embodiments described above.

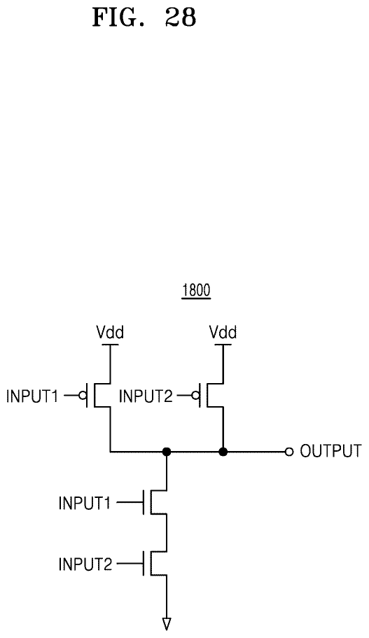

FIG. 28 is a circuit diagram of a CMOS NAND circuit 1800 according to an embodiment.

The CMOS NAND circuit 1800 includes a pair of CMOS transistors through which different input signals are transmitted. The CMOS NAND circuit 1800 may include the semiconductor device according to the embodiments described above.

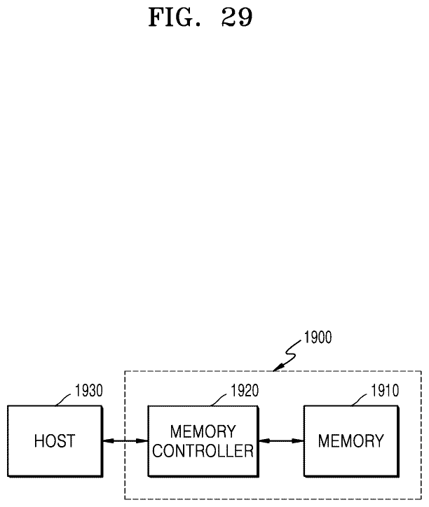

FIG. 29 is a block diagram illustrating an electronic device 1900 according to an embodiment.

The electronic device 1900 includes a memory 1910 and a memory controller 1920. The memory controller 1920 may control the memory 1910 to read data from the memory 1810 and/or write data to the memory 1910 in response to a request from the host 1930. At least one of the memory 1910 and the memory controller 1920 may include a semiconductor device according to the embodiments described above.

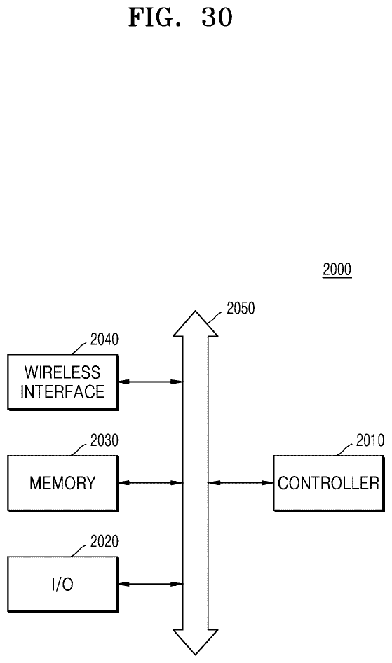

FIG. 30 is a block diagram of an electronic device 2000 according to an embodiment.

The electronic device 2000 may configure a wireless communication device, or a device capable of transmitting and/or receiving information under a wireless environment. The electronic device 2000 includes a controller 2010, an input/output device (I/O) 2020, a memory 2030, and a wireless interface 2040, which are interconnected with each other through a bus 2050.

The controller 2010 may include at least one of a microprocessor, a digital signal processor, or a processing device similar thereto. The input/output device 2020 may include at least one of a keypad, a keyboard, and a display. The memory 2030 may be used to store commands to be executed by the controller 2010. For example, the memory 2030 may be used to store user data. The electronic device 2000 may use the wireless interface 2040 to transmit/receive data through a wireless communication network. The wireless interface 2040 may include an antenna and/or a wireless transceiver. The electronic device 2000 may include the semiconductor device according to the embodiments described above.

The semiconductor device according to the embodiments may exhibit good electrical performance in a micro-structure, and thus may be applied to a logic device, a memory device, a display device, an integrated circuit device, and the like, and may implement miniaturization, low power, and high performance.

The semiconductor device, the electronic device, and the method of manufacturing the same have been described with reference to embodiments shown in the drawings. The semiconductor device according to the embodiments described above may reduce contact resistance by including a local region in which the indium content and the metal content of the metal oxide layer are adjusted.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a first electrode;
a second electrode spaced apart from the first electrode;
an oxide semiconductor layer between the first electrode and the second electrode;
a metal oxide layer between the oxide semiconductor layer and the first electrode, the metal oxide layer including indium (In) and a metal, the metal including at least one of tungsten (W) and ruthenium (Ru);
a gate insulating layer provided on the oxide semiconductor layer; and
a gate electrode on the gate insulating layer, wherein
the gate insulating layer is between the oxide semiconductor layer and the gate electrode, and
the metal oxide layer comprises a local region in which a content of the metal is greater than 0 at % and less than or equal to 20 at %, and a sum of a content of the indium and the content of the metal is more than or equal to 60 at %.

2. The semiconductor device of claim 1, wherein the local region is located in a region of 20% to 80% of a thickness of the metal oxide layer from a boundary between the first electrode and the metal oxide layer.

3. The semiconductor device of claim 1, wherein a region of the metal oxide layer in which the content of the indium in the metal oxide layer is higher than the content of the metal is located in a region of 20% or more of a thickness of the metal oxide layer from a boundary between the first electrode and the metal oxide layer.

4. The semiconductor device of claim 1, further comprising:
a buffer layer between the metal oxide layer and the oxide semiconductor layer, wherein
the buffer layer includes at least one of InO and ITO.

5. The semiconductor device of claim 1, wherein
the first electrode further comprises Zn, and
a content of Zn in the first electrode is greater than 0 at % and less than or equal to 10 at %.

6. The semiconductor device of claim 1, further comprising:
a second metal oxide layer between the oxide semiconductor layer and the second electrode, wherein
the metal oxide layer between the oxide semiconductor layer and the first electrode is a first metal oxide layer, and
the second metal oxide layer comprises the local region.

7. The semiconductor device of claim 1, wherein the oxide semiconductor layer comprises at least one of In, Zn, Sn, Ga, and Hf.

8. The semiconductor device of claim 1, wherein the content of the metal in the metal oxide layer is greater in a region relatively close to the first electrode than in a region relatively far from the first electrode.

9. The semiconductor device of claim 1, wherein the gate electrode surrounds a periphery of the oxide semiconductor layer.

10. The semiconductor device of claim 1, further comprising:
a substrate, wherein
the oxide semiconductor layer, the gate insulating layer, and the gate electrode are disposed in a horizontal direction on a surface of the substrate, and
the oxide semiconductor layer, the gate insulating layer, and the gate electrode extend lengthwise in a direction that is perpendicular to the surface of the substrate.

11. The semiconductor device of claim 1, wherein
a bottom portion of the oxide semiconductor layer contacts the first electrode,
a first vertical extension portion of the oxide semiconductor layer extends perpendicular to the first electrode from a first end of the bottom portion, and
a second vertical extension portion of the oxide semiconductor layer extends perpendicular to the first electrode from a second end of the bottom portion.

12. The semiconductor device of claim 1, further comprising:
a capacitor, wherein
the capacitor is electrically connected to the first electrode or the second electrode.

13. A method of manufacturing a semiconductor device, the method comprising:
forming a first electrode including at least one of tungsten (W) and ruthenium (Ru);
forming a buffer layer including indium (In) on the first electrode;
forming an oxide semiconductor layer on the buffer layer; and
forming a metal oxide layer between the first electrode and the oxide semiconductor layer by performing a heat treatment on a structure including the first electrode, the buffer layer, and the oxide semiconductor layer, wherein
the metal oxide layer includes a metal and the metal includes at least one of indium, tungsten (W), and ruthenium (Ru),
the metal oxide layer comprises a local region in which a content of the metal is greater than 0 at % and less than or equal to 20 at %, and a sum of a content of the indium and the content of the metal is more than or equal to 60 at %.

14. The method of claim 13, wherein the local region is located in a region of 20% or more of a thickness of the metal oxide layer from a boundary between the first electrode and the metal oxide layer.

15. The method of claim 13, wherein a region of the metal oxide layer in which the content of the indium in the metal oxide layer is higher than the content of the metal is located in a region of 20% or more of a thickness of the metal oxide layer from a boundary between the first electrode and the metal oxide layer.

16. The method of claim 13, wherein the buffer layer includes at least one of InO and ITO.

17. The method of claim 13, wherein the oxide semiconductor layer comprises at least one of In, Zn, Sn, Ga, and Hf.

18. The method of claim 13, wherein the content of the metal in the metal oxide layer is greater in a region relatively close to the first electrode than in a region relatively far from the first electrode.

19. The method of claim 13, wherein the buffer layer has a thickness greater than 3 nm and less than or equal to 7 nm.

20. The method of claim 13, wherein the heat treatment is performed at a temperature of 400° C. to 600° C.
